(19) United States
(12) Patent Application Publication
(10) Pub. No.: US 2003/0137061 A1
(43) Pub. Date: Jul. 24, 2003

(54) Encapsulation of organic polymer electronic devices

(76) Inventors: Phillip Bailey, Goleta, CA (US); Jorma Peltola, Santa Barbara, CA (US); Ian Parker, Santa Barbara, CA (US)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/373,817

(22) Filed: Feb. 26, 2003

Related U.S. Application Data
(63) Continuation of application No. 10/069,383, filed on Feb. 19, 2002.
Application No. 10/069,383 is a 371 of international application No. PCT/US00/24126, filed on Sep. 1, 2000.
(60) Provisional application No. 60/152,536, filed on Sep. 3, 1999.

(51) Int. Cl. H01L 23/28

(52) U.S. Cl. 257/787

(57) ABSTRACT

An electronic device configuration that prevents ambient moisture and oxygen from reacting with materials used in the fabrication of the devices and thus prevents ambient moisture and oxygen from deleteriously affecting device performance by use of an airtight enclosure comprising a porous drying agent.

### FIELD OF THE INVENTION

This invention relates to organic polymer-based electronic devices such as diodes, for example light-emitting diodes and light-detecting diodes. More specifically, this invention relates to fabrication processes and structures for such devices which lead to high device efficiencies and which promote commercially acceptable, long operating lives.

### BACKGROUND OF THE INVENTION

Solid state electronic devices fabricated with conjugated organic polymer layers have attracted attention. Conjugated polymer-based diodes and particularly light-emitting diodes (LEDs) and light-detecting diodes are especially attractive due to their potential for use in display and sensor technology. These references as well as all additional articles, patents and patent applications referenced herein are incorporated by reference.

This class of devices have a structure which includes a layer or film of an electrophotoactive conjugated organic polymer bounded on opposite sides by electrodes (anode and cathode) and carried on a solid substrate.

Generally, materials for use as active layers in polymer diodes and particularly LEDs include semiconducting conjugated polymers, such as semiconducting conjugated polymers which exhibit photoluminescence. In certain preferred settings, the polymers are semiconducting conjugated polymers which exhibit photoluminescence and which are soluble and processible from solution into uniform thin films.

The anodes of these organic polymer-based electronic devices are conventionally constructed of a relatively high work function metals and transparent nonstoichiometric semiconductors such as indium/tin-oxide. This anode serves to inject holes into the otherwise filled pi-band of the semiconducting, luminescent polymer.

Relatively low work function metals such as barium or calcium are preferred as the cathode material in many structures. Ultrathin layers of such low work function metals and their oxides are preferred. This low work function cathode serves to inject electrons into the otherwise empty pi*-band of the semiconducting, luminescent polymer. The holes injected at the anode and the electrons injected at the cathode recombine radiatively within the active layer and light is emitted.

Unfortunately, although the use of low work function materials is required for efficient injection of electrons from the cathode and for satisfactory device performance, low work function metals such as calcium, barium and strontium, and their oxidesare typically chemically reactive. They readily react with oxygen and water vapor at room temperature and even more vigorously at elevated temperatures. These reactions destroy their required low work function property and degrade the critical interface between the cathode material and the luminescent semiconducting polymer. This is a persistent problem which leads to fast decay of the device efficiency (and light output) during storage and during stress, especially at elevated temperature.

Other organic polymer-based solid state devices present similar stability problems. The construction of, and materials used in, photodetecting devices and arrays of devices are very similar to those found in polymer-based LEDs. The main differences between polymer-based LEDs and photodetectors are that extremely reactive low work function electrodes need not be used, and that the electrical polarity of the electrodes is often reversed. Nevertheless, moisture and oxygen react with the components of these devices and again lead to a decrease in device performance over time.

One approach to minimizing the deleterious effects of atmospheric exposure has involved enclosing the devices in a barrier to separate the active materials from oxygen and moisture. This approach has had some success but it does not always adequately address the problems caused by even those small amounts of moisture trapped within the enclosure or diffusing into the enclosure over time.

Kawami, et al in U.S. Pat. No. 5,882,761 discloses a method for packaging light emitting devices fabricated using thin films of luminescent organic molecules as the active layer that seeks to address the problem of water contamination. That patent describes the placement of a water-reactive solid compound such as sodium oxide within the enclosure for the device. This reactive compound covalently reacts with water in the enclosure and converts it into a solid product. As an example, the sodium oxide just noted reacts with water to yield solid sodium hydroxide. This patent describes that it employs these water-reactive compounds to remove water in order that the moisture is retained at high temperatures. Kawami et al. note that materials which physically absorb moisture cannot be used since the moisture will be discharged at high temperatures (for example, at 85° C.).

The solid compounds with which the water react in the Kawami patent are themselves very reactive and lead to reaction products which are likewise very reactive. Thus, any accidental contact between these compounds or reaction products with other components of the device or the device enclosure can be deleterious. Thus, there is a need for methods of encapsulation of organic polymer-based solid state electronic devices, said encapsulation being sufficient to prevent water vapor and oxygen from diffusing into the device and thereby limiting the useful lifetime.

In addition, many of the known processes for achieving a hermetic encapsulation of electronic devices require that the devices be heated to temperatures in excess of 300° C. during the encapsulation process. Most polymer-based light-emitting devices are not compatible with such high temperatures.

### SUMMARY OF THE INVENTION

The present invention relates to an electronic device containing a polymer electronic device including a pair of electrodes opposed to each other and an active polymer layer interposed between the electrodes; an airtight enclosure having an inner surface adjacent to the polymer electronic device and an opposing outer surface adjacent to an external atmosphere; a drying agent adjacent to the inner surface, the drying agent having a porous structure and being capable of trapping water by physically absorbing it into its porous structure; wherein the airtight enclosure encapsulates the polymer electronic device, to isolate the polymer electronic device and the drying agent from the external atmosphere. The present invention also relates to a method of fabricating a polymer electronic device with improved lifetime, by encapsulating the polymer electronic device iin an airtight enclosures with a solidy drying agent.

In a preferred embodiment the drying agent is incorporated into one or more layer(s) of a substrate supporting the polymer electronic device.

As used herein, the phrase “adjacent to” does not necessarily mean that one layer is immediately next to another layer, but rather to denote a location closer to a first surface (e.g., the drying agent is closer to the inner surface) when compared to a second surface (e.g., outer surface) opposing the first surface.

### BRIEF DESCRIPTION OF THE DRAWINGS

FIG. 1 is a schematic cross-sectional diagram of a representative device of the present invention;

FIG. 2 is a graph showing the effect of various desiccant materials on encapsulated device lifetime is compared at 85° C. under ambient humidity conditions;

FIG. 3 is a series of graphs comparing the effectiveness of water removal according to the present invention with water removal using the materials and methods of the prior art; and

FIG. 4 is a graph comparing the stability of water removal of the method of the present invention with the method of the prior art.

### DESCRIPTION OF PREFERRED EMBODIMENTS

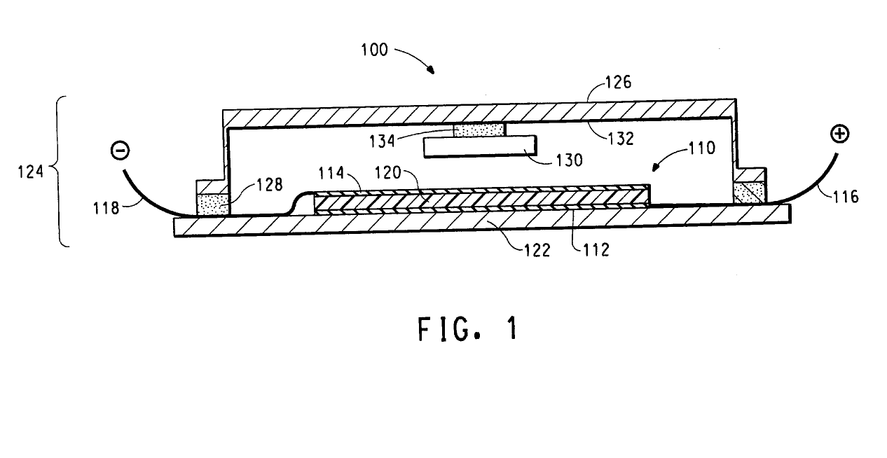

As best seen in FIG. 1, an electronic device 100 of the present invention includes a polymer electronic device 110 made up of the anode 112 and cathode 114 with electrical attaching leads 116, 118, the layer of electrically active organic polymer 120, and, in this preferred embodiment, a substrate 122. The device 110 also includes an encapsulating enclosure 124 isolating the electronic device from the atmosphere. This enclosure is made up of the substate 122 as a base with a cover or lid 126 affixed to the base 122 with a bonding agent 128. A drying agent 130 is encapsulated within the enclosure 124, preferably affixed to an inner surface 132 of the enclosure with a bonding agent 134.

The Substrate

The substrate 122 is typically impermeable to gases and moisture. In a preferred embodiment the substrate is glass. In a second preferred embodiment, the substrate is silicon. In a third preferred embodiment, the substrate is a flexible substrate such as an impermeable plastic or composite material comprising a combination of inorganic and plastic materials. Examples of useful flexible substrate include a sheet, or a multilayer laminate, of flexible material such as an impermeable plastic such as polyester, for example polyethylene terephthalate, or a composite material made up of a combination of plastic sheet with optional metallic or inorganic dielectric layers deposited thereupon. In a preferred embodiment, the substrate is transparent (or semitransparent) to enable light to enter into the encapsulated region or to enable light to be emitted from the encapsulated region through it.

The Enclosure

The airtight enclosure 126 isolates the polymer electronic device 110 from the atmosphere. How the airtight enclosure is formed is not crucial, so long as the process steps do not adversely affect the components of the polymer electronic device 110. For example, the airtight enclosure 126 may be formed of multiple pieces that are bonded together with a bonding agent. In a preferred embodiment the airtight enclosure includes a lid 126 bonded to a base. As best seen in FIG. 1, a preferred base 122 is the substrate of the polymer electronic device 110.

The material used to form the airtight enclosure 126 should be impermeable to gases and moisture. In one embodiment, the lid is made from metal. In another embodiment, the lid is made from glass or from a ceramic material. Plastics that are air-impermeable and water-impermeable can also be used.

The thickness of the lid 126 is not crucial to the present invention, so long as the lid 126 is thick enough to be a continuous barrier (with no voids or pinholes). Preferably, the lid 126 has a thickness of between about 10 and about 1000 μm. Where the base is not the substrate of the polymer electronic device (not shown), it is understood that the base can be made of the same material as the lid. As best seen in FIG. 1, the lid 126 is sealed to the substrate 122 with a bonding agent 128. This bonding agent should cure at a temperature below the decomposition temperature of the active layer 120, such as below 75° C. and preferably below 50° C. and preferably at ambient temperature or only moderately elevated temperatures. This is advantageous as it eliminates exposure to high temperatures common in the art which can often damage or degrade the electronic device 110. Preferred bonding agents include epoxies, either cured by exposure to ultraviolet light or by exposure to moderately elevated temperatures as just noted (or both). Various primer materials (not shown) may be used to assist in the bonding process. As best seen in FIG. 1, electrical leads 116, 118 emanate from the device. These leads 116, 118 should be sealed as wellm such as by the bonding agent 128. Alternative but functionally equivalent lead configurations can be used.

The Solid Drying Agent

Prior to sealing the lid 126 onto the substrate 122 and enclosing the electronic device 110, a solid drying agent (desiccant material) 130 is inserted. The form in which the desiccant is included is not important. For example, the drying agent 130 can be in the form of a powder in a porous packet, a pressed pellet, a solid contained within a gel, a solid contained within a cross-linked polymer, and/or a film. The drying agent can be placed within the enclosure 124 in a variety of ways. For example, the drying agent 130 can be incorporated in a coating on the substrate or on an inner surface of the lid (not shown), or, as best seen in FIG. 1, provided by affixing the drying agent 130 an inner surface 132 of the enclosure 124 with a bonding agent 134. Alternatively (not shown), the drying agent can be incorporated into a flexible substrate of the electronic device or one or more of the layers of a a multilayered or laminated substrate.

The nature of the solid drying agent is important. It is a porous solid, most commonly an inorganic solid having a controlled pore structure into which water molecules can travel but in which the water molecules undergo physical absorption so as to be trapped and not released into the environment inside the enclosure. Molecular sieves are one such material. In a preferred embodiment, the drying agent encapsulated into the sealed package is a zeolite. The zeolites are well known materials and are commercially available. In general, any zeolite suitable for trapping water may be used. The zeolites are known to consist of aluminum and silicon oxides in approximately equal amounts with sodium as the counter ion. The zeolite materials absorb moisture by physical absorption rather than by chemical reaction. Physical absorption is preferred.

In a still more preferred embodiment, the drying agent 130 encapsulated into the enclosure 124 is a zeolite material known as Tri-Sorb (available from Süd-Chemie Performance Packaging, a member of the Süd-Chemie Group, a division of United Catalysts Inc., located in Belen, N. Mex.). The structure of Tri-Sorb consists of aluminum and silicon oxides in approximately equal amounts with sodium as the counter ion. Tri-Sorb absorbs moisture by physical absorption. The remarkable improvement in stability and lifetime of the polymer LEDs when encapsulated with the methods described in this invention is illustrated in the Examples. In particular, encapsulation with the physically absorbing zeolite material as desiccant significantly outperforms barium-oxide as desiccant; said barium oxide absorbs moisture by chemical absorption.

The amount of drying agent to be added should be determined to assure that it provides adequate capacity to absorb the moisture trapped within the enclosure when it is sealed shut. The water uptake capacity of the drying agent is a known property. The volume of the interior of the device and the humidity of the air in the enclosure can be readily determined. Taking these factors into account an adequate weight of drying agent can be determined and incorporated.

In a preferred embodiment, drying agent in excess of the calculated amount can be added to compensate for any residual flux of water vapor into the active device area via imperfact edge seals and/or residual permeability of water vapor through the substrate.

The Active Layers

Among the promising materials for use as the active layers 120 in the electronic devices protected by the present invention, such as polymer LEDs, are poly(phenylene vinylene), PPV, and soluble derivatives of PPV such as, for example, poly(2-methyoxy-5-(2′-ethyl-hexyloxy)-1,4-phenylene vinylene), MEH-PPV, a semiconducting polymer with an energy gap e.g. of >2.1 eV. This material is described in more detail in U.S. Pat. No. 5,189,136. Another material described as useful in this application is poly(2,5-bis(cholestanoxy)-1,4-phenylene vinylene), BCHA-PPV, a semiconducting polymer with an energy gap e.g. of >2.2 eV. This material is described in more detail in U.S. patent application Ser. No. 07/800,555. Other suitable polymers include, for example, the poly(3-alkylthiophenes) as described by D. Braun, G. Gustafsson, D. McBranch and A. J. Heeger, J. Appl. Phys. 72, 564 (1992) and related derivatives as described by M. Berggren, O. Inganas, G. Gustafsson, J. Rasmusson, M. R. Andersson, T. Hjertberg and O. Wennerstrom; poly(paraphenylene) as described by G. Grem, G. Leditzky, B. Ullrich, and G. Leising, Adv. Mater. 4, 36 (1992), and its soluble derivatives as described by Z. Yang, I. Sokolik, F. E. Karasz in Macromolecules, 26, 1188 (1993), polyquinoline as described by I. D. Parker J. Appl. Phys, Appl. Phys. Lett. 65, 1272 (1994). Blends of conjugated semiconducting polymers in non-conjugated host polymers are also useful as the active layers in polymer LEDs as described by C. Zhang, H. von Seggern, K. Pakbaz, B. Kraabel, H. W. Schmidt and A. J. Heeger, Synth. Met., 62, 35 (1994). Also useful are blends comprising two or more conjugated polymers as described by H. Nishino, G. Yu, T-A. Chen, R. D. Rieke and A. J. Heeger, Synth. Met.,48, 243 (1995). Generally, materials for use as active layers in polymer LEDs include semiconducting conjugated polymers, more specifically semiconducting conjugated polymers which exhibit photoluminescence, and still more specifically semiconducting conjugated polymers which exhibit photoluminescence and which are soluble and processible from solution into uniform thin films.

The High Work Function Anodes

Suitable relatively high work function metals for use as anode materials 112 are transparent conducting thin films of indium/tin-oxide [H. Burroughs, D. D. C. Bradley, A. R. Brown, R. N. Marks, K. Mackay, R. H. Friend, P. L. Burns, and A. B. Holmes, Nature 347, 539 (1990); D. Braun and A. J. Heeger, Appl. Phys. Lett. 58, 1982 (1991)]. Alternatively, thin films of conducting polymers can be used as demonstrated by G. Gustafsson, Y. Cao, G. M. Treacy, F. Klavetter, N. Colaneri, and A. J. Heeger, Nature, 357, 477 (1992), by Y. Yang and A. J. Heeger, Appl. Phys. Lett 64, 1245 (1994) and U.S. patent application Ser. No. 08/205,519, by Y. Yang, E. Westerweele, C. Zhang, P. Smith and A. J. Heeger, J. Appl. Phys. 77, 694 (1995), by J. Gao, A. J. Heeger, J. Y Lee and C. Y Kim, Synth. Met., 82,221 (1996) and by Y. Cao, G. Yu, C. Zhang, R. Menon and A. J. Heeger, Appl. Phys. Lett. 70, 3191, (1997). Bilayer anodes comprising a thin film of indium/tin-oxide and a thin film of polyaniline in the conducting emeraldine salt form are preferred because, as transparent electrodes, both materials enable the emitted light from the LED to radiate from the device in useful levels.

The Low Work Function Cathodes

Suitable relatively low work function metals for use as cathode materials 114 are the alkaline earth metals such as calcium, barium, strontium and rare earth metals such as ytterbium. Alloys of low work function metals, such as for example alloys of magnesium in silver and alloys of lithium in aluminum, are also known in prior art (U.S. Pat. Nos. 5,047,687; 5,059,862 and 5,408,109). The thickness of the electron injection cathode layer has ranged from 200-5000 Å as demonstrated in the prior art (U.S. Pat. No. 5,151,629, U.S. Pat. No. 5,247,190, U.S. Pat. No. 5,317,169 and J. Kido, H. Shionoya, K. Nagai, Appl. Phys. Lett., 67 (1995) 2281). A lower limit of 200-500 Angstrom units (Å) is required in order to form a continuous film (full coverage) for cathode layer (U.S. Pat. No. 5,512,654; J. C. Scott, J. H. Kaufman, P. J. Brock, R. DiPietro, J. Salem and J. A. Goitia, J. Appl. Phys., 79 (1996) 2745; I. D. Parker, H. H. Kim, Appl. Phys. Lett., 64 (1994) 1774). In addition to good coverage, thicker cathode layers were believed to provide self-encapsulation to keep oxygen and water vapor away from the active parts of the device.

Electron-injecting cathodes comprising ultra-thin layers of alkaline earth metals, calcium, strontium and barium, have been described for polymer light-emitting diodes with high brightness and high efficiency. Compared to conventional cathodes fabricated from the same metals (and other low work function metals) as films with thickness greater than 200 Å, cathodes comprising ultra-thin layer alkaline earth metals with thicknesses less than 100 Å provide significant improvements in stability and operating life to polymer light emitting diodes (Y. Cao and G. Yu, U.S. patent application Ser. No. 08/872,657).

Electron-injecting cathodes comprising ultra-thin layers of the oxides of the alkaline earth metals, calcium, strontium and barium, have also been described for polymer light-emitting diodes with high brightness and high efficiency (Y. Cao et al. PCT Application No. US99/23775, filed Oct. 12, 1999)

The construction of, and materials used in, photodetecting devices and arrays of devices are very similar to the fabrication of polymer-based LEDs. The main differences between polymer-based LEDs and photodetectors is that reactive low work function electrodes need not be used, and that the electrical polarity of the electrodes is reversed. Nevertheless, hermetically sealed packaging is required for long lifetime of photodetecting devices fabricated from conducting polymers. Thus, the encapsulating enclosure of the present invention is also useful for such devices, said encapsulation being sufficient to prevent water vapor and oxygen from diffusing into the device and thereby limiting the useful lifetime.

This invention will be further described with reference being made to the following examples. These examples are provided solely to illustrate various modes for practicing this invention and are not to be construed as limiting its scope.

### EXAMPLE 1

A zeolite-based desiccant (Tri-Sorb) was used as the drying agent or desiccant. As an example of a polymer-based electronic device, a polymer light-emitting diode (LED) array was used.

An air- and water-impermeable lid made of glass, containing a desiccating tablet composed of zeolite (available from Süd-Chemie Performance Packaging, a member of the Süd-Chemie Group, a division of United Catalysts Inc., located in Belen, N. Mex.), was used to encapsulate the LED array and thereby isolate it from the atmosphere.

The drying agent was enclosed in the package by fixing the drying agent on the internal surface of the impermeable lid by use of a thermal curing epoxy resin (Araldite 2014, Ciba Specialty Chemicals Corp., East Lansing, Mich.) as a bonding agent.

The drying agent was in the form of a compressed pellet of powder. The impermeable lid was attached to the substrate using a bonding agent. The completed device had the structure 100 shown in FIG. 1. The lid was sealed to a substrate made of glass, using Araldite 2014 as a bonding agent.

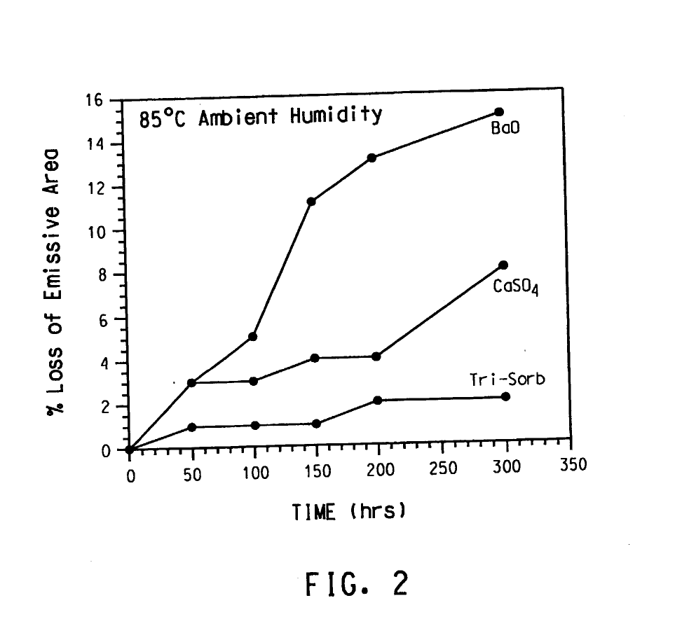

Immediately after sealing the package, the dimensions of the light-emitting pixels were measured. The packaged devices were then placed for an extended period in an 85° C. oven with ambient humidity. At fifty (50) hour intervals, the devices were removed from the oven and the dimensions of the light-emitting pixels were re-measured. Degradation of the polymer electronic devices due to moisture and oxygen was quantified by the loss in the active area. In this particular example, the loss of light-emitting area for a pixellated LED display was measured. As can be seen from FIG. 2, the Tri-Sorb drying agent resulted in less than a 2% loss in light-emitting area after 300 hours storage at 85° C.

Also, as can be seen from FIG. 2, the zeolite-based desiccant (in this case a specific example going under the trade-name of Tri-Sorb) considerably outperformed the other examples, notably BaO and CaSO₄ (which are desiccant materials previously known is the art as useful desiccant materials (U.S. Pat. No. 5,882,761). This example shows that zeolite-based drying agents can be very effective drying agents even at high temperatures.

### EXAMPLE 2

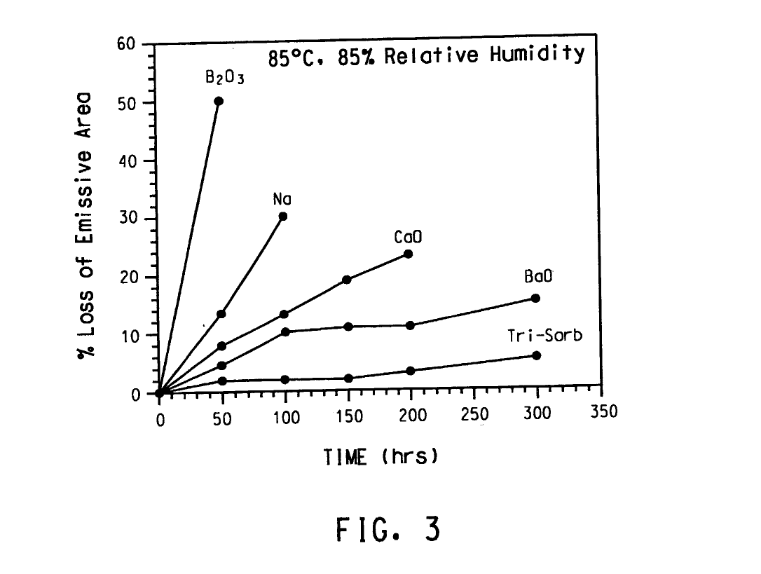

The experiments in Example 1 were repeated except that the storage conditions were modified to include high humidity, i.e. 85° C./85% relative humidity. As can be seen from FIG. 3, polymer LED arrays showed less than 5% loss of emissive area after 300 hours.

Also seen from FIG. 3, the zeolite system is superior to many other drying agents including BaO and CaO (which are desiccant materials previously patented as effective desiccant materials (U.S. Pat. No. 5,882,761).

This example shows that zeolite-based drying agents are very effective drying agents even at high temperatures in high humidity environments.

### EXAMPLE 3

The experiments in Example 1 were repeated except the form of the drying agent was a powder contained in a porous packet which was fixed on the internal surface of the impermeable lid by use of a bonding agent. The loss of emissive area was comparable to the data shown in FIGS. 2 and 3.

This example shows that the particular physical form of the drying agent is not important.

### EXAMPLE 4

Thermogravimetric weight-loss studies were performed on Tri-Sorb and BaO were compared for their performance in permanently removing water from an electronic device enclosure. Standard, calibrated thermogravimetric equipment was used. Tablets of Tri-Sorb and BaO were heated (from room temperature to 400° C.) in a dry atmosphere, while the mass of the tablets were continually monitored. No hysteresis was observed.

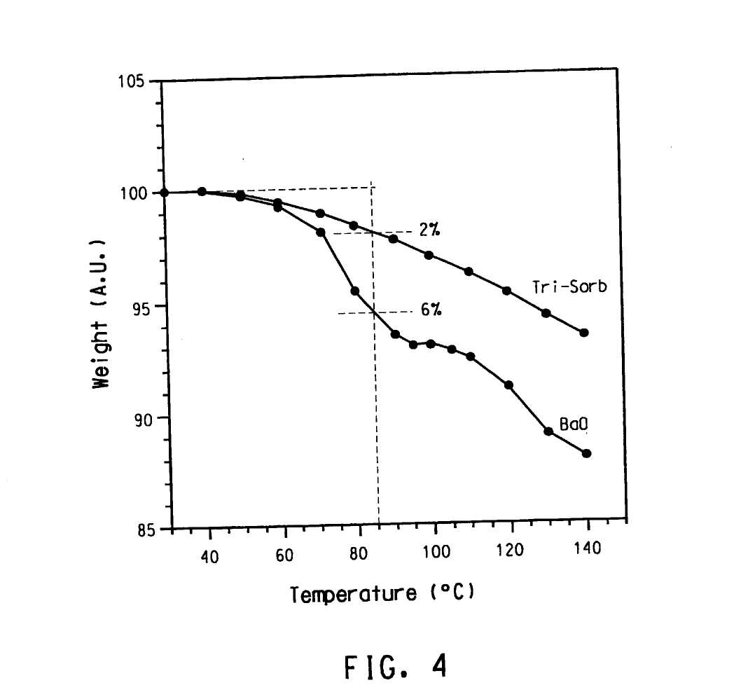

The results are shown in FIG. 4. At room temperature both samples have absorbed moisture. As they are heated, they both released this water due to thermodynamic processes and the sample weight decreases. However, as can be seen, the Tri-Sorb releases less moisture. At 85° C., the Tri-Sorb sample has released three times less water than the BaO sample.

This example shows that Tri-Sorb has better water retention properties at high temperature than does BaO (which was patented by Pioneer as a good drying agent at 85° C.).

As seen by the description above, the invention provides a technique for encapsulating polymeric light-emitting devices at the lowest possible method temperatures. The method of encapsulation advantageously offers a hermetic seal between the device and the ambient air with its harmful moisture and oxygen. In addition, the present method for encapsulation provides an overall thickness of the device is not significantly increased by the encapsulation of the device. Furthermore, the present encapsulation method requires fewer individual process steps than methods known to the art.

What is claimed is:

1. An electronic device (100) comprising:
a polymer electronic device (110) including a pair of electrodes (112, 114) opposed to each other and an active polymer layer (120) interposed between the electrodes;
an airtight enclosure (124) having an inner surface (132) adjacent to the polymer electronic device and an opposing outer surface adjacent to an external atmosphere;
a drying agent (130) adjacent to the inner surface, said drying agent having a porous structure and being capable of trapping water by physically absorbing it into its porous structure;
wherein the airtight enclosure encapsulates the polymer electronic device, to isolate the polymer electronic device and the drying agent from the external atmosphere.

2. A method for fabricating a long-lived, organic polymer-based electronic device comprising:
providing a polymer electronic device (110) having a pair of electrodes (112, 114) opposed to each other and an active polymer layer (120) interposed between the electrodes;
encapsulating in an airtight enclosure (124) said polymer electronic device in combination with a solid drying agent (130) having a porous structure which is capable of trapping water by physically absorbing it into its porous structure, said enclosure isolating the device and the drying agent from an external atmosphere.

3. The electronic device of claim 1 and/or the method of claim 2, wherein the polymer electronic device comprises a substrate including at least one substrate layer, such that the solid drying agent is incorporated in one or more of the at least one substrate layer.

4. The electronic device of claim 1 and/or the method of claim 2, wherein the drying agent is a molecular sieve.

5. The electronic device of claim 1 and/or the method of claim 2, wherein the drying agent comprises zeolite.

6. The electronic device of claim 1 and/or the method of claim 2, wherein the drying agent comprises Trisorb.

7. The electronic device of claim 1 and/or the method of claim 2, wherein the drying agent present in the enclosure is spaced apart from the electrodes and the polymer layer.

8. The electronic device of claim 1 and/or the method of claim 2, wherein the drying agent is present on a surface within said airtight enclosure.

9. The electronic device of claim 1 and/or the method of claim 2, wherein the polymer electronic device additionally comprises a substrate that supports the polymer layer and the electrodes, wherein the drying agent is present on a surface of said substrate.

10. The electronic device of claim 1 and/or the method of claim 2, wherein the drying agent is attached to a surface within said airtight enclosure

11. The electronic device of claim 1 and/or the method of claim 2, wherein the drying agent is bonded to a surface within said airtight enclosure

12. The electronic device of claim 1 and/or the method of claim 2, wherein the drying agent is present as a pressed pellet.

13. The electronic device of claim 1 and/or the method of claim 2, wherein the drying agent is present as a powder contained in a porous packet.

14. The electronic device of claim 1 and/or the method of claim 2, wherein the drying agent is present as a solid contained in a porous gel.

15. The electronic device of claim 1 and/or the method of claim 2, wherein the drying agent is present as a solid contained in a membrane.

16. The electronic device of claim 1 and/or the method of claim 2, wherein the drying agent is present as a solid contained in a bonding agent.

17. The electronic device of claim 1 and/or the method of claim 2, wherein the pair of electrodes includes an anode and a cathode, and the cathode comprises a water-reactive low work function metal or metal oxides.

18. The electronic device of claim 1 and/or the method of claim 2, wherein the pair of electrodes includes an anode and a cathode, said cathode comprises a water-reactive low work function-alkaline earth metal or metal oxide.

19. The electronic device of claim 1 and/or the method of claim 2, wherein the pair of electrodes includes an anode and a cathode, said cathode comprises a water-reactive material selected from calcium, barium, strontium, calcium oxide, barium oxide and strontium oxide.

20. The electronic device of claim 1 and/or the method of claim 2, wherein said polymer electronic device is a light-emitting diode.

21. The electronic device of claim 1 and/or the method of claim 2, wherein said polymer electronic device is a light-responsive detector.

22. The electronic device of claim 1 and/or the method of claim 2, wherein said airtight enclosure is formed of multiple pieces bonded together with bonding agent.

23. The electronic device of claim 1 and/or the method of claim 2, wherein said bonding agent is a low temperature bonding agent.

24. The electronic device of claim 1 and/or the method of claim 2, wherein said low temperature bonding agent is an epoxy.

25. The electronic device of claim 1 and/or the method of claim 2, wherein said airtight enclosure comprises a base bonded to a lid.

26. The electronic device of claim 1 and/or the method of claim 2, wherein the polymer electronic device additionally comprises a substrate which supports the polymer layer and the electrodes and wherein said airtight enclosure comprises a base bonded to a lid with the substrate serving as the base.
